(19) United States
(12) Patent Application Publication
(10) Pub. No.: US 2006/0218327 A1
(43) Pub. Date: Sep. 28, 2006

(54) Information handling system including detection of an audio input device

(75) Inventors: Soo Yen Lee, Austin, TX (US); Stephanus Saputro, Austin, TX (US)

Correspondence Address: HAYNES AND BOONE, LLP, 901 MAIN STREET, SUITE 3100, DALLAS, TX, 75202, US

(73) Assignee: Dell Products L.P., Round Rock, TX (US)

(21) Appl. No.: 11/087,967

(22) Filed: Mar. 23, 2005

(51) Int. Cl. G06F 13/00; H03F 21/00

(52) U.S. Cl. 710/107; 381/120

(57) ABSTRACT

An information handling system (“IHS”) including a processor is provided. The IHS also includes an audio input device interface coupled to the processor. Moreover, the IHS includes a voltage regulator coupled to the interface for determining whether an audio input device is coupled to the interface. The voltage regulator also supplies power to the audio input device in response to determining that an audio input device is coupled to the interface.

### BACKGROUND

The description herein relates generally to information handling systems (“IHSs”) and more particularly to IHSs including detection of an audio input device.

As the value and use of information continues to increase, individuals and businesses seek additional ways to process and store information. One option is an IHS. An IHS generally processes, compiles, stores, and/or communicates information or data for business, personal, or other purposes. Because technology and information handling needs and requirements may vary between different applications, IHSs may also vary regarding what information is handled, how the information is handled, how much information is processed, stored, or communicated, and how quickly and efficiently the information may be processed, stored, or communicated. The variations in IHSs allow for IHSs to be general or configured for a specific user or specific use such as financial transaction processing, airline reservations, enterprise data storage, or global communications. In addition, IHSs may include a variety of hardware and software components that may be configured to process, store, and communicate information and may include one or more computer systems, data storage systems, and networking systems.

Some IHSs include an interface (e.g., a connector) that is suitable for coupling (e.g., connecting) an audio input device (e.g., an external microphones) to such IHSs so that the IHS is capable of receiving audio signals from such audio input device. For increasing quality of audio signals received via the audio input device, the IHSs also include a voltage regulator (e.g., low dropout regulator (“LDO”)) for providing regulated (e.g., clean) power to the audio input device via the interface.

Although a voltage regulators included by an IHS is capable of increasing quality of audio signals received via an audio input device, such voltage regulator may also cause various problems. For example, the voltage regulator may increase the IHS′ power requirement by consuming additional power even when an audio input device is not coupled to the IHS. Such consumption of additional power may reduce an amount of time that a portable IHS (e.g., a laptop or a notebook computer) is capable of operating with power supplied from a battery.

Accordingly, what is needed is a method and an IHS for detecting an audio input device without the disadvantages discussed above.

### SUMMARY

A method and an IHS is provided for detecting an audio input device. The method provides for determining whether an audio input device is coupled to an IHS. The method also includes, in response to determining that an audio input device is coupled to the IHS, activating a voltage regulator that supplies power to the audio input device.

### BRIEF DESCRIPTION OF THE DRAWINGS

FIG. 1 is a block diagram of an information handling system, according to an illustrative embodiment.

FIG. 2 is a block diagram of additional circuitry included in the IHS of FIG. 1.

FIG. 3 is a block diagram of an interconnection between an audio input device interface and a voltage regulator, according to one embodiment.

FIG. 4 is a block diagram of an interconnection between an audio input device interface and a voltage regulator, according to another embodiment.

FIG. 5 is a flow chart of operations performed by the IHS of FIG. 1.

### DETAILED DESCRIPTION

For purposes of this disclosure, an information handling system (“IHS”) may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an IHS may be a personal computer, a PDA, a consumer electronic device, a network server or storage device, a switch router or other network communication device, or any other suitable device and may vary in size, shape, performance, functionality, and price. The IHS may include memory, one or more processing resources such as a central processing unit (CPU) or hardware or software control logic. Additional components of the IHS may include one or more storage devices, one or more communications ports for communicating with external devices as well as various input and output (I/O) devices, such as a keyboard, a mouse, and a video display. The IHS may also include one or more buses operable to transmit communications between the various hardware components.

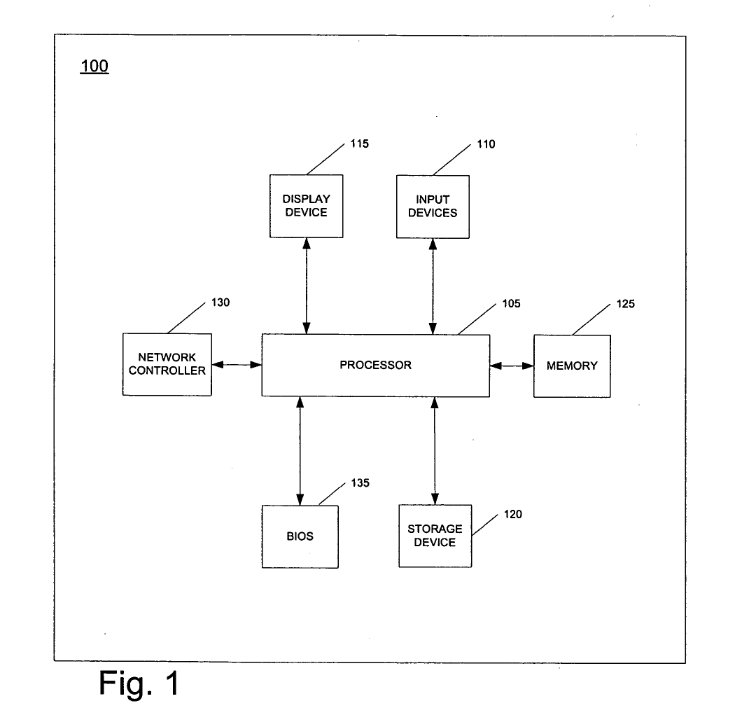

FIG. 1 is a block diagram of an IHS, indicated generally at 100, according to the illustrative embodiment. The IHS 100 includes a processor 105 (e.g., an Intel Pentium series processor) for executing an otherwise processing instructions, input devices 110 for receiving information from a human user, a display device 115 (e.g., a conventional electronic cathode ray tube (“CRT”) device) for displaying information to the user, a storage device 120 (e.g., a non-volatile storage device such as a hard disk drive or other computer readable medium or apparatus) for storing information, a memory device 125 (e.g., random access memory (“RAM”) device and read only memory (“ROM”) device), also for storing information, and a network controller 130 for communicating between the IHS 100 and a network. Each of the input devices 110, the display device 115, the storage device 120, the memory device 125, and the network controller 130 is coupled to the processor 105, and to one another. In one example, the IHS 100 includes various other electronic circuitry for performing other operations of the IHS 100, such as a print device (e.g., a ink-jet printer or a laser printer) for printing visual images on paper.

The input devices 110 includes, for example, a conventional keyboard and a pointing device (e.g., a “mouse”, a roller ball, or a light pen). A user operates the keyboard to input alphanumeric text information to the processor 105, and the processor receives such information from the keyboard. A user also operates the pointing device to input cursor-control information to the processor 105, and the processor 105 receives such cursor-control information from the pointing device.

The IHS 100 also includes a basic input/output system (“BIOS”) 135. The BIOS 135 includes instructions executed by the processor 105, so that the IHS 100 is capable of performing basic operations without executing instructions (e.g., instructions included by an operating system (“OS”) stored by the storage device 120. In one example the BIOS 135 is stored by a ROM (e.g., the memory device 125).

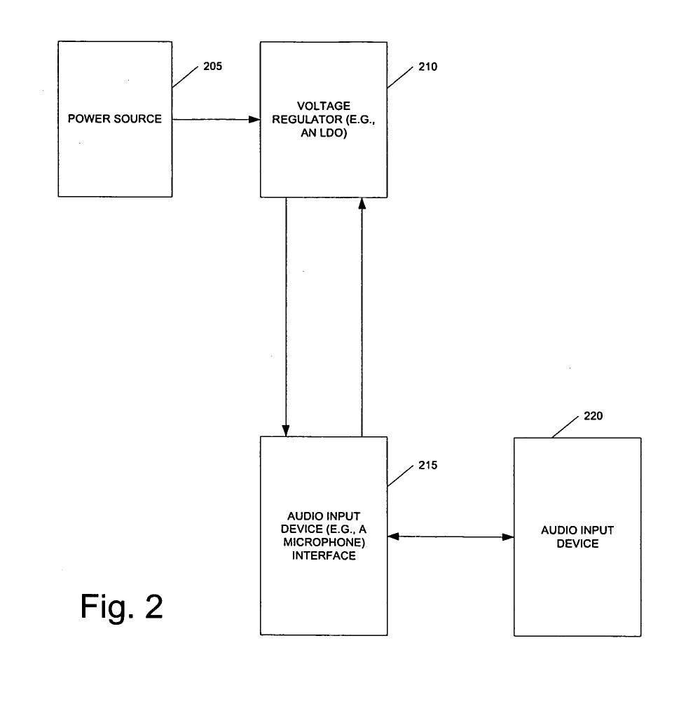

FIG. 2 is a block diagram of additional circuitry included in the IHS 100. As shown in FIG. 2, the IHS 100 also includes a power source 205. Moreover, the IHS 100 includes a voltage regulator (e.g., a low dropout (“LDO”) regulator) 210 coupled to the power source 205 (e.g., via a power rail), and an audio input device interface (e.g., a microphone interface) 215 that is coupled to the voltage regulator 210. Via the audio input interface 215, the IHS 100 is capable of being coupled to an audio input device (e.g., a microphone) 220. The audio input device 220 is an example of the input devices 110 of FIG. 1.

The additional circuitry depicted in FIG. 2 is susceptible to impurity (e.g., noise) in power supplied by the power source 205. The voltage regulator 210 “regulates” such power supplied by the power source to the audio input device 220 via the audio input device interface 215. Accordingly, the voltage regulator 210 is capable of increasing the quality of audio signals received from the audio input device 220.

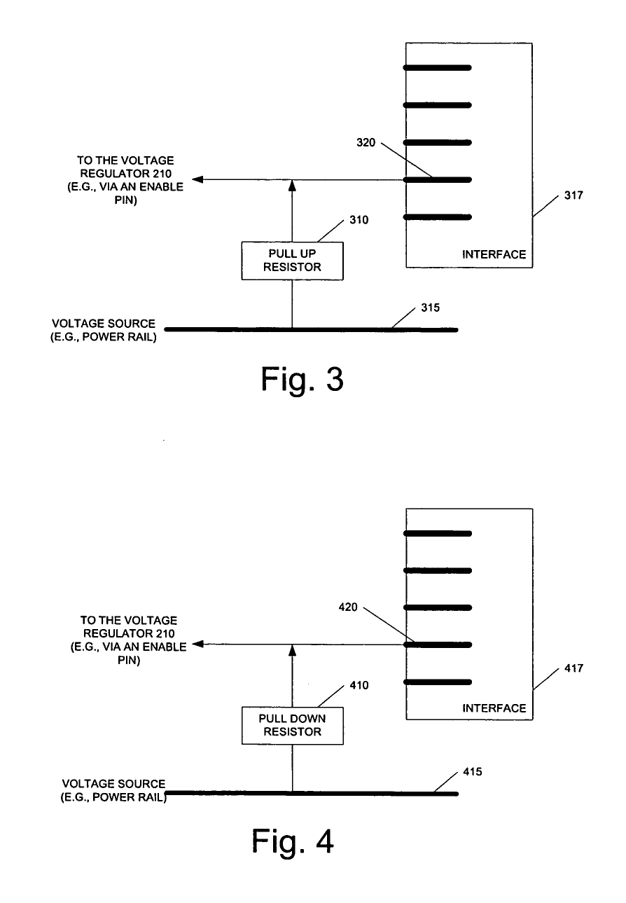

Although it is capable increasing the quality of audio signal received from the audio input device 220, the voltage regulator 210 is also capable consuming additional power by consuming power even while an audio input device (e.g., the audio input device 220) is not coupled to the IHS. Accordingly, the IHS 100 determines whether an audio input device (e.g., the audio input device 220) is coupled to the IHS 100 via the audio input device interface 215 as discussed in more detail below in connection with FIGS. 3 and 4. Also, in response to determining that an audio input device is coupled to the IHS 100, the IHS 100 activates (e.g., powers on or enables) the voltage regulator 210. Moreover, in response to determining that an audio input device is not coupled to the IHS 100, the IHS 100 deactivates (e.g., powers off or disables) the voltage regulator 210.

Accordingly, FIG. 3 is a more detailed block diagram of interconnection between an audio input device interface and a voltage regulator, according to one embodiment. A pull up resistor 310 is coupled to a voltage source (e.g., a power rail) 315. The pull up resistor 310 is also coupled to an unused pin 320 of an audio input device interface 317, which is representative of the interface 215 of FIG. 2. Moreover, each of the pin 320 and the pull up resistor 310 is coupled to the voltage regulator 210 (e.g., via an enable pin included in the voltage regulator 210). Because the pull up resistor “pulls up” the unused pin 320's signal to a voltage of the voltage source 315, a default state (i.e., a first state) of the unused pin 320 is high. Accordingly, such default state is an indication that an audio input device is not coupled to the IHS 100 via the interface 317. By comparison, in response to an audio input device being coupled to the IHS 100 via the interface 317, the unused pin 320 assumes a second state (e.g., low state). Accordingly, the unused pin 320's state being low indicates that an audio input device is coupled to the IHS 100 via the interface 317.

FIG. 4 is a more detailed block diagram of interconnection between an audio input device interface and a voltage regulator, according to another embodiment. Similar to the detection circuit 305 of FIG. 3, the IHS 100 includes a resistor 410. However, in this embodiment, the resistor 410 is a pull down resistor. The pull down resistor 410 is coupled to a voltage source 415. The pull down resistor 410 is also coupled to an unused pin 420 of an audio input interface 417, which is representative of the audio input interface 215 of FIG. 2. Moreover, each of the pin 420 and the pull down resistor 410 is coupled to the voltage regulator 210 (e.g., via an enable pin included in the voltage regulator 210). Because the pull down resistor “pulls down” the unused pin 420's signal to a low state, the unused pin 420's first state is low. Such low state of the unused pin 420 indicates that an audio input device is not coupled to the IHS 100 via the interface 417. However, in response to an audio input device being coupled to the IHS 100 via the interface 417, the unused pin 420 assumes a second state (e.g., a high state). Accordingly, the unused pin 420's state being high indicates that an audio input device is coupled to the IHS 100 via the interface 417.

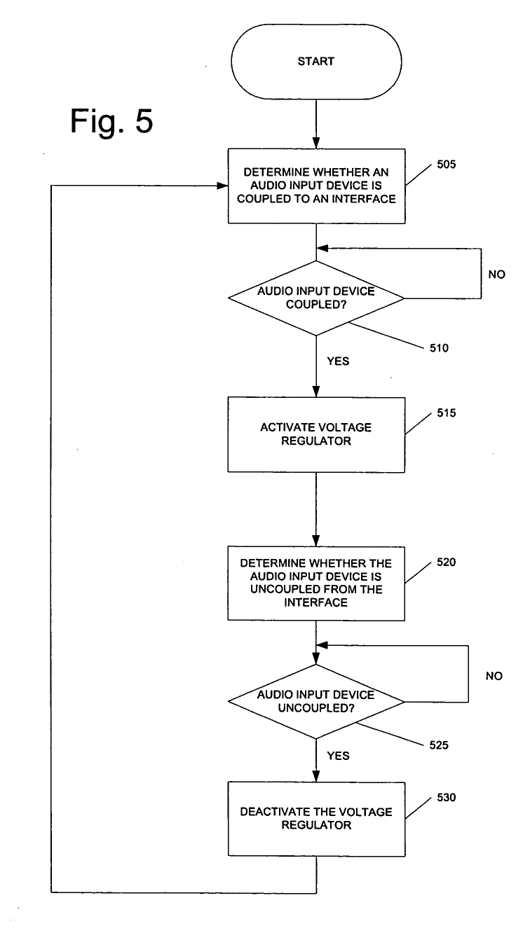

As discussed in below (in connection with FIG. 5), in response to determining that it is coupled to an audio input device, the IHS 100 activates the voltage regulator 210, thereby outputting (e.g., supplying) power to such audio input device. Also, in response to determining that it is not coupled to an audio input device, the IHS 100 deactivates the voltage regulator 210, which does not supply power to such audio input device. In this way, the IHS 100 is capable of reducing an amount of power consumed by the voltage regulator 210.

Accordingly, FIG. 5 is a flow chart of operations performed by the IHS 100 for activating and deactivating the voltage regulator 210 in response to determining whether an audio input device is coupled to the IHS 100. The operation begins at a step 505, where the IHS 100 determines whether an audio input device is coupled to the interface 215. As discussed above (in connection with FIGS. 3 and 4), the IHS 100 determines that an audio input device is coupled to the interface 215 in response to determining that a state, of an unused pin included in the interface 215, is a second state and otherwise determines that an audio input device is not coupled the interface 215 in response to determining that the state of the unused pin is a first state. Also, as discussed above in connection with FIGS. 3 and 4, in one embodiment, the first state is high and the second state is low. In another embodiment, the first state is low, and the second state is high. After the step 505, the operation continues to a step 510.

At the step 510, in response to the IHS 100 determining that it is coupled to an audio input device, the operation continues to a step 515. Otherwise the operation self-loops.

At the step 515, the IHS 100 activates the voltage regulator 210. In one example, the voltage regulator 210 activates itself in response to detecting a specified state (e.g., a low state or a high state discussed above in connection with the step 505) on its enable pin that is coupled to the interface 215's unused pin. After the step 515, the operation continues to a step 520.

At the step 520, the IHS 100 determines whether the audio input device that was coupled is now uncoupled from the interface 215, as discussed above in connection with the step 505. After the step 520, the operation continues to a step 525.

At the step 525, in response to determining that the audio input device is now uncoupled from the interface 215, the operation continues to a step 530. Otherwise, the operation self-loops as shown in FIG. 5.

At the step 530, the IHS 100 deactivates the voltage regulator 210. In one example, the voltage regulator 210 deactivates itself in response to detecting a state, on its enable pin, that is different from the specified state of the step 515. After the step 530, the operation returns to the step 505.

Although illustrative embodiments have been shown and described, a wide range of modification, change and substitution is contemplated in the foregoing disclosure. Also, in some instances, some features of the embodiments may be employed without a corresponding use of other features. Accordingly, it is appropriate that the appended claims be constructed broadly and in manner consistent with the scope of the embodiments disclosed herein.

What is claimed is:

1. A method comprising:
determining whether an audio input device is coupled to an information handling system (“IHS”); and
in response to determining that an audio input device is coupled to the IHS, activating a voltage regulator that supplies power to the audio input device.

2. The method of claim 1, further comprising:
in response to determining that an audio input device is not coupled to the IHS, deactivating the voltage regulator that supplies power to the audio input device.

3. The method of claim 2, wherein determining whether an audio input device is coupled to the IHS includes:
determining whether an audio input device is coupled to an audio input device interface included in the IHS.

4. The method of claim 3, wherein the interface is an external microphone interface.

5. The method of claim 3, wherein determining whether an audio input device is coupled to the interface includes:
in response to determining that an unused pin, of the interface, is in a first state, determining that an audio input device is not coupled to the interface; and
in response to determining that the unused pin is in a second state, determining that an audio input device is coupled to the interface.

6. The method of claim 5, wherein the unused pin is pin 4.

7. The method of claim 5, wherein the first state is high and the second state is low.

8. The method of claim 5, wherein the first state is low and the second state is high.

9. The method of claim 1, wherein the voltage regulator is a low dropout regulator (“LDO”).

10. The method of claim 1, wherein the IHS is a portable IHS.

11. An information handling system (“IHS”) comprising:
a processor;
an audio input device interface coupled to the processor; and
a voltage regulator coupled to the interface for:
determining whether an audio input device is coupled to the interface; and
in response to determining that an audio input device is coupled to the interface, supplying power to the audio input device.

12. The IHS of claim 11, wherein the voltage regulator is further for:
in response to determining that an audio input device is not coupled the interface, not supplying power to the audio input device.

13. The IHS of claim 12, wherein determining whether an audio input device is coupled to the interface includes:
in response to determining that an unused pin, of the interface, is in a first state, determining that an audio input device is not coupled to the interface; and
in response to determining that the unused pin is in a second state, determining that an audio input device is coupled to the interface.

14. The IHS of claim 13, wherein the unused pin is pin 4.

15. The IHS of claim 13, and comprising:
a pull-up resistor coupled to the unused pin and the voltage regulator, wherein the first state is high and the second state is low.

16. The IHS of claim 13, and comprising:
a pull-down resistor coupled to the unused pin and the voltage regulator, wherein the first state is low and the second state is high.

17. The IHS of claim 11, wherein the voltage regulator is a low dropout regulator (“LDO”).

18. The IHS of claim 11, wherein the interface is an external microphone interface.

19. The IHS of claim 11, wherein supplying power to the audio input device is by activating the voltage regulator.

20. The IHS of claim 11, wherein the IHS is a portable IHS.
